(19) United States
(12) Patent Application Publication
(10) Pub. No.: US 2026/0173405 A1
(43) Pub. Date: Jun. 18, 2026

(54) SEMICONDUCTOR STRUCTURE AND FABRICATION METHOD THEREOF

(71) Applicant: PEKING UNIVERSITY, Beijing (CN)

(72) Inventors: Zongwei WANG, Beijing (CN); Yimao CAI, Beijing (CN); Gaoqi YANG, Beijing (CN)

(73) Assignee: PEKING UNIVERSITY, Beijing (CN)

(21) Appl. No.: 19/422,196

(22) Filed: Dec. 16, 2025

(30) Foreign Application Priority Data
Dec. 17, 2024 (CN) 202411865490.1

(51) Int. Cl. H10B 63/00; H10N 70/00

(52) U.S. Cl. CPC H10B 63/845; H10B 63/20; H10N 70/041; H10N 70/826; H10N 70/8616; H10N 70/8822; H10N 70/8825; H10N 70/8828; H10N 70/8833; H10N 70/8836; H10N 70/884

(57) ABSTRACT

The present disclosure relates to a semiconductor structure and a fabrication method thereof. The semiconductor structure includes: a substrate; a first conductive structure disposed on the substrate; a memory cell disposed on a side of the first conductive structure away from the substrate, the memory cell including a first electrode layer, a first functional layer, a second functional layer, and a second electrode layer sequentially stacked in a direction away from the substrate, the memory cell forming a second hole above the first conductive structure, an opening direction of the second hole facing away from the substrate, and one of the first functional layer and the second functional layer being a selector layer, and the other being a resistive switching layer.

### CROSS-REFERENCE TO RELATED APPLICATIONS

The present application claims priority to Chinese patent application No. 2024118654901, filed on Dec. 17, 2024, the entire content of which is incorporated herein by reference.

### TECHNICAL FIELD

The present disclosure relates to the field of integrated circuit technologies, and in particular, to a semiconductor structure and a fabrication method thereof.

### BACKGROUND

Since the advent of Moore's Law, the industry has proposed various semiconductor device designs and process optimizations to meet the demands for current products.

However, with the continuous development in fields such as artificial intelligence and autonomous driving, higher requirements have been put forward for memory, such as higher integration density and better reliability.

### SUMMARY

Accordingly, it is necessary to provide a semiconductor structure and a fabrication method thereof to address the requirement in the related art for higher integration density and better reliability of memory.

In a first aspect, a semiconductor structure is provided in the present disclosure. The semiconductor structure includes: a substrate; a first conductive structure disposed on the substrate; a memory cell disposed on a side of the first conductive structure away from the substrate, the memory cell including a first electrode layer, a first functional layer, a second functional layer, and a second electrode layer sequentially stacked in a direction away from the substrate, the memory cell forming a second hole above the first conductive structure, and an opening direction of the second hole facing away from the substrate, and one of the first functional layer and the second functional layer being a selector layer, and the other being a resistive switching layer; and a second conductive structure disposed on a side of the memory cell away from the substrate, the second conductive structure being in contact with the second electrode layer on a sidewall and a bottom wall of the second hole.

Optionally, the semiconductor structure further includes: an isolation layer disposed on a side of the first conductive structure away from the substrate. The isolation layer is penetrated by a first hole. The memory cell is disposed corresponding to the first hole and forms the second hole above the first hole, the first electrode layer covers the first conductive structure on a bottom wall of the first hole, a sidewall of the first hole, and a portion of a top surface of the isolation layer peripheral to the first hole, and the first functional layer, the second functional layer, and the second electrode layer sequentially cover the first electrode layer.

Optionally, the memory cell further includes an intermediate layer disposed between the first functional layer and the second functional layer. A material of the intermediate layer includes at least one of amorphous carbon, silicon carbide, tellurium carbide, tellurium carbon sulfide, molybdenum sulfide, tungsten sulfide, molybdenum telluride, indium gallium zinc oxide, indium aluminum zinc oxide, tin-doped indium oxide, manganese telluride, tungsten telluride, or zinc-doped indium oxide.

Optionally, a material of the selector layer includes at least one of niobium oxide, vanadium oxide, iron oxide, neodymium nickel oxide, samarium nickel oxide, lanthanum cobalt oxide, gadolinium cobalt oxide, germanium telluride, aluminum telluride, boron telluride, germanium selenide, germanium sulfide, or antimony telluride. A material of the resistive switching layer includes at least one of tantalum oxide, titanium oxide, hafnium oxide, zirconium oxide, silicon oxide, magnesium oxide, aluminum nitride, germanium antimony telluride, scandium antimony telluride, indium silver antimony telluride, germanium antimonide, germanium telluride, antimony telluride, copper sulfide, germanium sulfide, germanium selenide, zinc sulfide, aluminum borate, strontium titanate, zirconium titanate, barium titanate, hafnium zirconium oxide, or hafnium aluminum oxide.

Optionally, the memory cell further includes a barrier layer disposed between the selector layer and the first electrode layer, or between the selector layer and the second electrode layer. An electron affinity of the barrier layer is less than an electron affinity of the selector layer. A material of the barrier layer includes at least one of zinc oxide, nickel oxide, titanium oxide, chromium oxide, molybdenum oxide, tungsten oxide, bismuth oxide, antimony oxide, barium titanate, indium oxide, vanadium oxide, strontium titanate, aluminum titanate, manganese oxide, or gallium nitride.

Optionally, the memory cell further includes a buffer layer disposed between the selector layer and the barrier layer. An electron affinity of the buffer layer is between the electron affinity of the selector layer and the electron affinity of the barrier layer. A material of the buffer layer includes at least one of titanium oxide, nickel oxide, zinc oxide, chromium oxide, molybdenum oxide, tungsten oxide, bismuth oxide, antimony oxide, indium oxide, vanadium oxide, niobium oxide, manganese oxide, neodymium oxide, strontium oxide, germanium oxide, lanthanum oxide, hafnium oxide, gallium oxide, aluminum oxide, zirconium oxide, silicon oxide, ytterbium oxide, or magnesium oxide.

In a second aspect, a method for fabricating a semiconductor structure is provided in the present disclosure. The method includes the following steps: providing a substrate, and forming a first conductive structure on the substrate; forming an isolation layer on a side of the first conductive structure away from the substrate, and etching the isolation layer to form a first hole, the first hole exposing a portion of a top surface of the first conductive structure; forming a first electrode layer, a first functional layer, a second functional layer, and a second electrode layer sequentially to form a memory cell, the memory cell forming a second hole above the first conductive structure, an opening direction of the second hole facing away from the substrate, and one of the first functional layer and the second functional layer being a selector layer, and the other being a resistive switching layer; and forming a second conductive structure on a side of the memory cell away from the substrate, the second conductive structure being in contact with the second electrode layer on a sidewall and a bottom wall of the second hole.

Optionally, a material of the selector layer includes at least one of niobium oxide, vanadium oxide, iron oxide, neodymium nickel oxide, samarium nickel oxide, lanthanum cobalt oxide, gadolinium cobalt oxide, germanium telluride, aluminum telluride, boron telluride, germanium selenide, germanium sulfide, or antimony telluride. A material of the resistive switching layer includes at least one of tantalum oxide, titanium oxide, hafnium oxide, zirconium oxide, silicon oxide, magnesium oxide, aluminum nitride, germanium antimony telluride, scandium antimony telluride, indium silver antimony telluride, germanium antimonide, germanium telluride, antimony telluride, copper sulfide, germanium sulfide, germanium selenide, zinc sulfide, aluminum borate, strontium titanate, zirconium titanate, barium titanate, hafnium zirconium oxide, or hafnium aluminum oxide. After forming the first functional layer and the second functional layer, an annealing treatment is performed on both the first functional layer and the second functional layer.

Optionally, forming the memory cell further includes: forming an intermediate layer between the first functional layer and the second functional layer.

Optionally, forming the memory cell further includes: forming a barrier layer between the selector layer and the first electrode layer, or between the selector layer and the second electrode layer, where an electron affinity of the barrier layer is less than an electron affinity of the selector layer; and forming the memory cell further includes: forming a buffer layer between the selector layer and the barrier layer. An electron affinity of the buffer layer is between the electron affinity of the selector layer and the electron affinity of the barrier layer.

One or more embodiments of the present disclosure will be described in detail below with reference to drawings. Other features, objects and advantages of the present disclosure will become more apparent from the description, drawings, and claims.

### BRIEF DESCRIPTION OF THE DRAWINGS

In order to describe the technical solutions in the embodiments of the present disclosure or the conventional technology more clearly, the following will briefly introduce the accompanying drawings required for describing the embodiments or the conventional technology. Apparently, the accompanying drawings in the following description are merely embodiments of the present disclosure, and for a person of ordinary skill in the art, other drawings can be obtained based on the disclosed drawings without making any creative efforts.

FIG. 1 is a schematic diagram of a semiconductor structure provided in an embodiment.

FIG. 2 is a schematic diagram of a semiconductor structure provided in another embodiment.

FIG. 3 is a schematic diagram of a semiconductor structure provided in yet another embodiment.

FIG. 4 is a process flowchart of a method for fabricating a semiconductor structure provided in an embodiment.

FIG. 5 is a schematic diagram of a structure after forming a first conductive structure on the substrate provided according to an embodiment.

FIG. 6 is a schematic diagram of a structure after forming an isolation layer on a side of a first conductive structure away from a substrate provided in an embodiment.

FIG. 7 is a schematic diagram of a structure after etching an isolation layer to form a first hole provided in an embodiment.

FIG. 8 is a schematic diagram of a structure after forming a first electrode layer, a first functional layer, a second functional layer, and a second electrode layer sequentially provided in an embodiment.

FIG. 9 is a schematic diagram of a structure after forming a memory cell provided in an embodiment.

FIG. 10 is a schematic diagram of a structure after forming a second conductive structure provided in an embodiment.

### DETAILED DESCRIPTION OF THE EMBODIMENTS

In order to facilitate understanding of the present disclosure, the present disclosure will be described more comprehensively below with reference to the relevant accompanying drawings. Embodiments of the present disclosure are shown in the accompanying drawings. However, the present disclosure can be implemented in many different forms and is not limited to the embodiments described herein. On the contrary, the purpose of providing these embodiments is to make the present disclosure more thorough and comprehensive.

As used herein, the singular forms “a”, “an” and “the” may also include the plural forms, unless the context clearly indicates otherwise. It should also be understood that the terms “includes/comprises” or “has” etc. designate the presence of stated features, integers, steps, operations, components, parts or combinations thereof, but do not preclude the possibility of the presence or addition of one or more other features, integers, steps, operations, components, parts or combinations thereof.

Unless otherwise defined, all technical and scientific terms used herein have the same meanings as commonly understood by those skilled in the art to which the present disclosure belongs. The terms used in the specification of the present disclosure herein are only for the purpose of describing specific embodiments and are not intended to limit the present disclosure.

A 1S1R (One Selector-One Resistor) architecture is composed of a selector (as a threshold switching device) and a memristive device (such as a resistive random-access memory, RRAM). The selector has a threshold switching characteristic. When an applied voltage or current exceeds a certain threshold, the selector switches from a high-resistance state to a low-resistance state, allowing current to pass through. In RRAM, leakage current may occur when in the low-resistance state. However, in the 1S1R architecture, the threshold switching characteristic of the selector can effectively suppress leakage current in non-selected cells, thereby improving the stability and reliability of the memory.

Memories with the 1S1R architecture feature smaller feature sizes, low power consumption, and high reliability, which facilitate achieving high-density storage. Nevertheless, with the continuous scaling down of the critical dimensions of integrated circuit devices, the three-dimensional integration of memories with the 1S1R architecture still faces challenges.

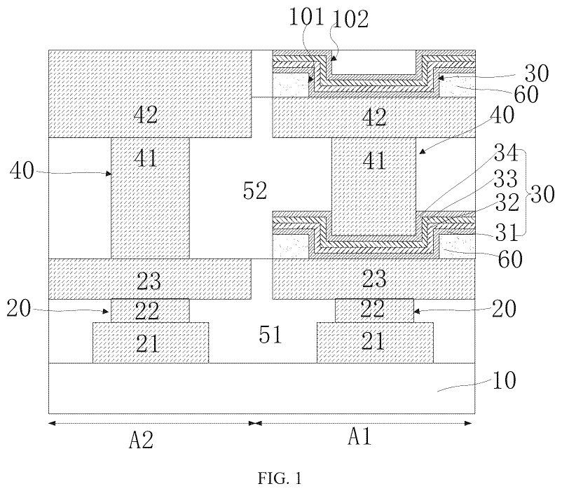

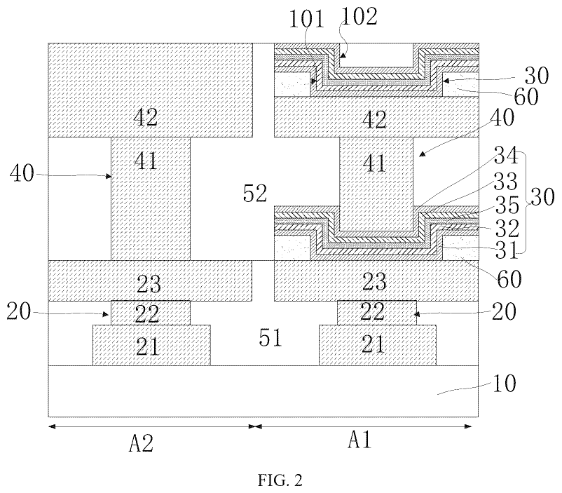

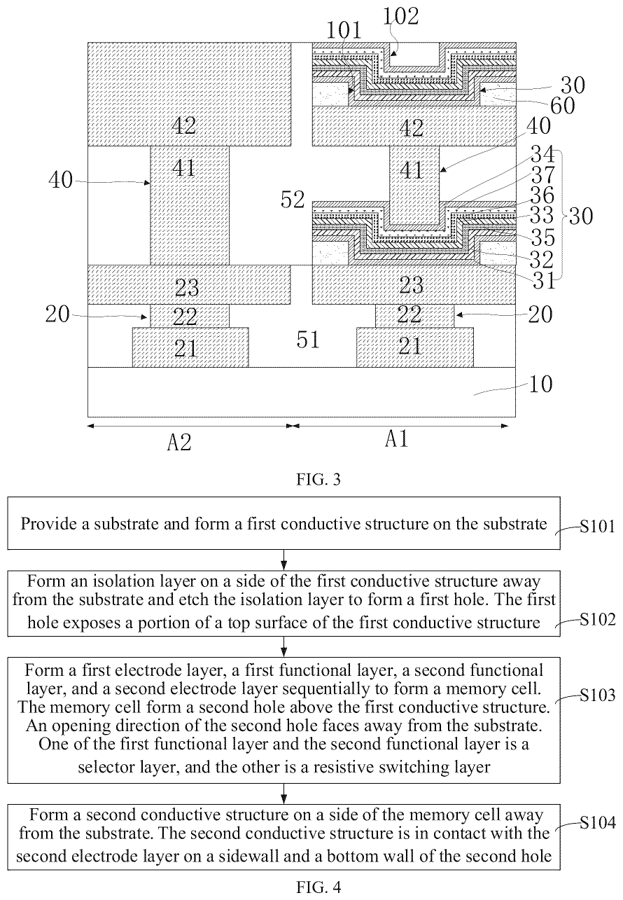

According to an exemplary embodiment, a semiconductor structure is provided in the present disclosure. Referring to FIG. 1, FIG. 2, or FIG. 3, the semiconductor structure includes a substrate 10, a first conductive structure 20, a memory cell 30, and a second conductive structure 40. The first conductive structure 20 is disposed on the substrate 10. The memory cell 30 is disposed on a side of the first conductive structure 20 away from the substrate 10. The memory cell 30 includes a first electrode layer 31, a first functional layer 32, a second functional layer 33, and a second electrode layer 34 sequentially stacked in a direction away from the substrate 10. The memory cell 30 forms a second hole 102 above the first conductive structure 20, and an opening direction of the second hole 102 faces away from the substrate 10. One of the first functional layer 32 and the second functional layer 33 is a selector layer, and the other is a resistive switching layer. The second conductive structure 40 is disposed on a side of the memory cell 30 away from the substrate 10. The second conductive structure 40 is in contact with the second electrode layer 34 on a sidewall and a bottom wall of the second hole 102.

The substrate 10 includes a memory region A1 and a logic region A2. Both the memory region A1 and the logic region A2 are formed with a first conductive structure 20. The first conductive structure 20 may be a conductive line or wiring structure embedded in a first dielectric layer 51, and is configured to transmit current within the semiconductor structure. A material of the first conductive structure 20 includes metals (such as copper, aluminum, etc.) or metal alloys, providing good conductive properties. The first conductive structure 20 may further include a diffusion barrier layer disposed between the first dielectric layer 51 and the metal material such as copper, aluminum, etc. The diffusion barrier layer is configured to support the first conductive structure 20, and isolate the first conductive structure 20 from other film layers to prevent the diffusion of conductive material. A material of the diffusion barrier layer may include titanium, tantalum, etc. In this embodiment, the first conductive structure 20 includes a first conductive layer 21, a second conductive layer 22, and a third conductive layer 23 sequentially connected in a direction perpendicular to the substrate 10. The first conductive layer 21, the second conductive layer 22, and the third conductive layer 23 may be conductive lines or pads arranged in a direction extending from the substrate 10.

The memory cell 30 is disposed on a side of the first conductive structure 20 in the memory region A1 away from the substrate 10, and the memory cell 30 is in contact connection with a top surface of the first conductive structure 20. In this embodiment, the memory cell 30 adopts the 1S1R memory architecture, and includes the first electrode layer 31, the first functional layer 32, the second functional layer 33, and the second electrode layer 34 sequentially stacked on the first conductive structure 20. One of the first functional layer 32 and the second functional layer 33 is a selector layer, and the other of the first functional layer 32 and the second functional layer 33 is a resistive switching layer. The selector layer blocks current at low voltages and allows current to pass at high voltages, preventing current from flowing through other unselected memory cells 30 when a specific memory cell 30 is selected for read/write operations, thereby avoiding crosstalk issues. The resistance of the resistive switching layer can switch between a high-resistance state and a low-resistance state under current excitation, enabling data storage.

The first electrode layer 31, which serves as the bottom electrode of the memory cell 30, is connected to both the first conductive structure 20 and the first functional layer 32. The second electrode layer 34, which serves as the top electrode of the memory cell 30, is connected to the second functional layer 33. The first electrode layer 31 is configured to be connected to an external circuit. The memory cell 30 can be operated through the first electrode layer 31 and the second electrode layer 34 to activate the selector layer and perform read/write operations on the resistive switching layer.

The memory cell 30 forms the second hole 102 above the first conductive structure 20, and an opening direction of the second hole 102 faces away from the substrate 10. The second conductive structure 40 is disposed on a side of the memory cell 30 away from the substrate 10, and is in contact with the second electrode layer 34 on the sidewall and the bottom wall of the second hole 102. The second conductive structure 40 may be a conductive line or wiring structure embedded in a second dielectric layer 52, and is configured to transmit current within the semiconductor structure. In this embodiment, the second conductive structure 40 includes a fourth conductive layer 41 and a fifth conductive layer 42 sequentially connected in a direction perpendicular to the substrate 10, and the fourth conductive layer 41 and the fifth conductive layer 42 may be conductive lines or pads arranged in a direction extending from the substrate 10. Both the memory region A1 and the logic region A2 are formed with the second conductive structure 40, and the second conductive structure 40 in the logic region A2 is connected to the first conductive structure 20.

According to the semiconductor structure of this embodiment, by configuring the memory cell 30 to form the second hole 102 facing away from the substrate 10, the contact area between the second conductive structure 40 and the second electrode layer 34 is increased, which can increase a drive current of the second conductive structure 40 for driving the memory cell 30. Consequently, when the first functional layer 32 is the selector layer and the second functional layer 33 is the resistive switching layer, increasing the contact area between the second conductive structure 40 and the second electrode layer 34 is beneficial to improving the read/write capability and read/write speed of the memory cell 30. When the first functional layer 32 is the resistive switching layer and the second functional layer 33 is the selector layer, increasing the contact area between the second conductive structure 40 and the second electrode layer 34 is beneficial to improving the gating capability and gating rate of the memory cell 30.

In some embodiments, as shown in FIG. 1, FIG. 2, or FIG. 3, the memory cell 30 further includes an isolation layer 60. The isolation layer 60 is disposed on the side of the first conductive structure 20 away from the substrate 10, and is penetrated by a first hole 101. The memory cell 30 is disposed corresponding to the first hole 101 and forms the second hole 102 above the first hole 101. The first electrode layer 31 covers the first conductive structure 20 on a bottom wall of the first hole 101, a sidewall of the first hole 101, and a portion of a top surface of the isolation layer 60 peripheral to the first hole 101. The first functional layer 32, the second functional layer 33, and the second electrode layer 34 sequentially cover the first electrode layer 31.

The isolation layer 60 is disposed on the side of the first conductive structure 20 away from the substrate 10, and is configured to isolate adjacent electrical devices, avoiding current leakage or interference between devices.

For example, a material of the isolation layer 60 may include at least one of silicon oxide, silicon nitride, or nitrogen-doped silicon oxide.

In some embodiments, the memory cells 30 are arranged spaced apart in a direction perpendicular to the substrate 10, and the memory cells 30 are connected through the second conductive structure 40.

In some embodiments, as shown in FIG. 2 or FIG. 3, the memory cell 30 further includes an intermediate layer 35 disposed between the first functional layer 32 and the second functional layer 33. In this way, the memory cell 30 includes the first electrode layer 31, the first functional layer 32, the intermediate layer 35, the second functional layer 33, and the second electrode layer 34 sequentially stacked. The intermediate layer 35 can prevent the performance degradation of the memory cell 30 caused by the mutual diffusion of materials between the first electrode layer 31 and the first functional layer 32, thereby improving the reliability and performance stability of the memory cell 30.

Further, a thermal conductivity of the intermediate layer 35 is less than that of the resistive switching layer. In this way, the intermediate layer 35 prevents the transfer of heat from the selector layer to the resistive switching layer, which can shorten the time required for the selector layer to reach its turn-on temperature and reduce a turn-on voltage (Vth) of the memory cell 30. Meanwhile, the intermediate layer 35 can improve the thermal stability of the selector layer, delay the temperature decrease of the selector layer, and reduce a write voltage and read voltage of the memory cell 30.

For example, a thermal conductivity of the selector layer is 0.3 W/m·K to 1.5 W/m·K. A thermal conductivity of the resistive switching layer is 2.2 W/m·K to 5 W/m·K. The thermal conductivity of the intermediate layer 35 is 0.2 W/m·K to 2 W/m·K.

In an example, the thermal conductivity of the selector layer is 0.3 W/m·K, the thermal conductivity of the resistive switching layer is 2.2 W/m·K, and the thermal conductivity of the intermediate layer 35 is 0.2 W/m·K. In another example, the thermal conductivity of the selector layer is 1.5 W/m·K, the thermal conductivity of the resistive switching layer is 5 W/m·K, and the thermal conductivity of the intermediate layer 35 is 2 W/m·K. In another example, the thermal conductivity of the selector layer is 1 W/m·K, the thermal conductivity of the resistive switching layer is 4 W/m·K, and the thermal conductivity of the intermediate layer 35 is 3 W/m·K.

Further, an electrical conductivity of the intermediate layer 35 ranges from 10⁻⁷ S/m to 10⁻² S/m, for example, 10⁻⁷ S/m, 10⁻⁶ S/m, 10⁻⁵ S/m, 10⁻⁴ S/m, 10⁻³ S/m, or 10⁻² S/m. In this way, the intermediate layer 35 has good conductivity and certain thermal insulation properties, so that when the intermediate layer 35 is disposed between the selector layer and the resistive switching layer, it does not affect the conduction between the selector layer and the resistive switching layer, and can also reduce a turn-on voltage of the memory cell 30.

In some embodiments, a material of the intermediate layer 35 includes at least one of amorphous carbon, silicon carbide, tellurium carbide, tellurium carbon sulfide, molybdenum sulfide, tungsten sulfide, molybdenum telluride, indium gallium zinc oxide, indium aluminum zinc oxide, tin-doped indium oxide, manganese telluride, tungsten telluride, or zinc-doped indium oxide.

The intermediate layer 35 may be a single-layer structure or a multi-layer structure. For example, the intermediate layer 35 may include a single amorphous carbon layer. Alternatively, the intermediate layer 35 may include a stacked structure composed of an amorphous carbon layer and an indium gallium zinc oxide layer.

In some embodiments, a material of the selector layer includes at least one of niobium oxide, vanadium oxide, iron oxide, neodymium nickel oxide, samarium nickel oxide, lanthanum cobalt oxide, gadolinium cobalt oxide, germanium telluride, aluminum telluride, boron telluride, germanium selenide, germanium sulfide, or antimony telluride.

The selector layer may be a single-layer structure or a multi-layer structure. For example, the selector layer may include a single niobium oxide layer. Alternatively, the selector layer may include a stacked structure composed of a niobium oxide layer and an antimony telluride layer.

A material of the resistive switching layer includes at least one of tantalum oxide, titanium oxide, hafnium oxide, zirconium oxide, silicon oxide, magnesium oxide, aluminum nitride, germanium antimony telluride, scandium antimony telluride, indium silver antimony telluride, germanium antimonide, germanium telluride, antimony telluride, copper sulfide, germanium sulfide, germanium selenide, zinc sulfide, aluminum borate, strontium titanate, zirconium titanate, barium titanate, hafnium zirconium oxide, or hafnium aluminum oxide.

The resistive switching layer may be a single-layer structure or a multi-layer structure. For example, the resistive switching layer may include a single tantalum oxide layer. Alternatively, the resistive switching layer may include a stacked structure composed of a tantalum oxide layer and a titanium oxide layer.

According to the semiconductor structure of this embodiment, by reasonably selecting the materials for the selector layer and the resistive switching layer of the memory cell 30 to ensure their compatibility, the memory cell 30 achieves a self-rectifying effect, which can effectively suppress the generation of leakage current in the memory cell 30, facilitates further reducing the size of the memory cell 30, improves the integration density of the memory cells 30 in the semiconductor structure, and expands the application fields and scenarios for the memory cell 30.

A material of the first electrode layer 31 may include at least one of vanadium (V), niobium (Nb), ruthenium (Ru), tungsten (W), tantalum (Ta), tantalum nitride (TaN), titanium (Ti), titanium nitride (TiN), titanium tungsten (TiW), aluminum (Al), titanium aluminum tungsten (TiAlW), yttrium (Ir), yttrium oxide (IrO₂), indium tin oxide (ITO), aluminum titanium nitride (TiAlN), aluminum nitride (AlNₓ), aluminum titanium nitride (TiAlN or AlTiN), hafnium (Hf), iridium (Ir), manganese (Mn), zinc (Zn), platinum (Pt), palladium (Pd), or copper (Cu). The first electrode layer 31 may be a single-layer structure or a multi-layer structure.

The material selection range of the second electrode layer 34 is the same as that of the first electrode layer 31, and will not be repeated here.

In some embodiments, as shown in FIG. 3, the memory cell 30 further includes a barrier layer 36 disposed between the selector layer and the first electrode layer 31, or between the selector layer and the second electrode layer 34. An electron affinity of the barrier layer 36 is less than that of the selector layer. A material of the barrier layer 36 includes at least one of zinc oxide, nickel oxide, titanium oxide, chromium oxide, molybdenum oxide, tungsten oxide, bismuth oxide, antimony oxide, barium titanate, indium oxide, vanadium oxide, strontium titanate, aluminum titanate, manganese oxide, or gallium nitride.

In some examples, the first functional layer 32 is the selector layer, the second functional layer 33 is the resistive switching layer, and the memory cell 30 includes the first electrode layer 31, the barrier layer 36, the first functional layer 32, the intermediate layer 35, the second functional layer 33, and the second electrode layer 34 sequentially stacked. The barrier layer 36 is configured to localize electrons and prevent electron leakage, thereby reducing a leakage current of the memory cell 30.

In other examples, the first functional layer 32 is the resistive switching layer, the second functional layer 33 is the selector layer, and the memory cell 30 includes the first electrode layer 31, the resistive switching layer, the intermediate layer 35, the selector layer, the barrier layer 36, and the second electrode layer 34 sequentially stacked.

In some embodiments, the memory cell 30 further includes a buffer layer 37 disposed between the selector layer and the barrier layer 36. An electron affinity of the buffer layer 37 is between the electron affinity of the selector layer and the electron affinity of the barrier layer 36. A material of the buffer layer 37 includes at least one of titanium oxide, nickel oxide, zinc oxide, chromium oxide, molybdenum oxide, tungsten oxide, bismuth oxide, antimony oxide, indium oxide, vanadium oxide, niobium oxide, manganese oxide, neodymium oxide, strontium oxide, germanium oxide, lanthanum oxide, hafnium oxide, gallium oxide, aluminum oxide, zirconium oxide, silicon oxide, ytterbium oxide, or magnesium oxide.

The buffer layer 37 is configured to buffer a difference in electron affinity between the selector layer and the barrier layer 36, avoiding performance fluctuations in the memory cell 30 caused by an excessively large difference in electron affinity between the selector layer and the barrier layer 36. Meanwhile, when the memory cell 30 is turned on, and the selector layer transitions from the high-resistance state to the low-resistance state, the voltage drop across the barrier layer 36 increases. By disposing the buffer layer 37 between the selector layer and the barrier layer 36 in the present disclosure, the buffer layer 37 can reduce the voltage drop across the barrier layer 36, preventing the barrier layer 36 from being broken down by high voltage drop, further reducing the leakage risk of the memory cell 30, improving the performance stability and reliability of the memory cell 30, and facilitating optimizing the performance of the device and extending its service life.

In some embodiments, an example where the first functional layer 32 is the selector layer and the second functional layer 33 is the resistive switching layer is taken for description. A difference between a work function of the first electrode layer 31 and the electron affinity of the selector layer is greater than 2 eV. A difference between a work function of the second electrode layer 34 and the electron affinity of the barrier layer 36 is greater than 2 eV.

The electron affinity of the selector layer is 2 eV to 4.5 eV. The electron affinity of the barrier layer 36 is 1 eV to 2 eV. The electron affinity of the buffer layer 37 is 1 eV to 4.5 eV.

In this way, a surface of one side of the selector layer is in contact with the first electrode layer 31, thus forming a barrier at the interface between the selector layer and the first electrode layer 31. A barrier is formed at the interface between a surface of the barrier layer 36 away from the buffer layer 37 and the second electrode layer 34. In this way, electrons can be localized at the barrier interface between the selector layer and the first electrode layer 31, and at the barrier interface between the barrier layer 36 and the second electrode layer 34, preventing electron leakage, and thereby reducing the leakage current of the memory cell 30.

In some embodiments, the intermediate layer 35 is disposed between the first functional layer 32 and the second functional layer 33 of the memory cell 30, and the buffer layer 37 and the barrier layer 36 are sequentially stacked between the selector layer and its adjacent electrode layer.

According to the semiconductor structure of this embodiment, by configuring the memory cell 30 to form the second hole 102 on the first conductive structure 20, the contact area between the second conductive structure 40 and the second electrode layer 34 is increased, which improves the read/write capability and speed of the memory cell 30. By reasonably selecting the materials for the selector layer and the resistive switching layer, the memory cell 30 achieves a self-rectifying effect, suppressing the leakage current and enabling size reduction, which facilitates improving the integration density of the memory cell 30. The design incorporating the barrier layer 36 and the buffer layer 37 can further reduce the leakage current of the memory cell 30 and improve the performance stability and reliability of the semiconductor structure.

According to an exemplary embodiment, a method for fabricating a semiconductor structure is further provided in the present disclosure. As shown in FIG. 4, the method includes the following steps S101 to S104.

In the step S101, a substrate is provided and a first conductive structure is formed on the substrate.

In the step S102, an isolation layer is formed on a side of the first conductive structure away from the substrate and the isolation layer is etched to form a first hole exposing a portion of a top surface of the first conductive structure.

In the step S103, a first electrode layer, a first functional layer, a second functional layer, and a second electrode layer are sequentially formed to form a memory cell. The memory cell forms a second hole above the first conductive structure. An opening direction of the second hole facing away from the substrate. One of the first functional layer and the second functional layer is a selector layer, and the other is a resistive switching layer.

In the step S104, a second conductive structure is formed on a side of the memory cell away from the substrate. The second conductive structure is in contact with the second electrode layer on a sidewall and a bottom wall of the second hole.

According to the method for fabricating the semiconductor structure in the present embodiment, before forming the memory cell, the isolation layer is first formed on the first conductive structure and etched to form the first hole penetrating through the isolation layer. The memory cell is then formed within the first hole, configured to form the second hole facing away from the substrate. Then, the second conductive structure is formed filling the second hole, which can increase the contact area between the second conductive structure and the second electrode layer and increase the drive current of the second conductive structure for driving the memory cell. Consequently, when the first functional layer is the selector layer and the second functional layer is the resistive switching layer, increasing the contact area between the second conductive structure and the second electrode layer is beneficial to improving the read/write capability and read/write speed of the memory cell. When the first functional layer is the resistive switching layer and the second functional layer is the selector layer, increasing the contact area between the second conductive structure and the second electrode layer is beneficial to improving the gating capability and gating rate of the memory cell.

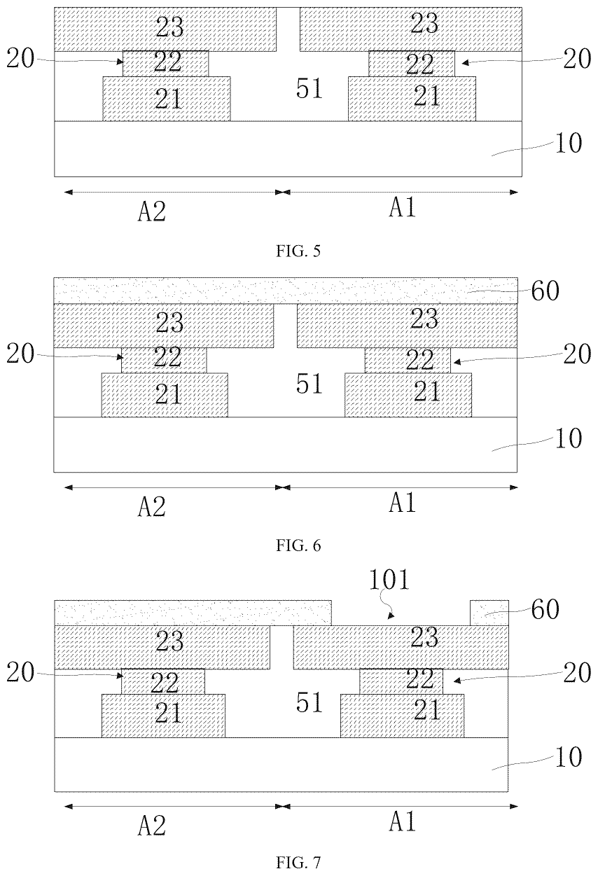

In the step S101, as shown in FIG. 5, the substrate 10 may be a semiconductor substrate. A material of the semiconductor substrate includes silicon (Si), germanium (Ge), silicon germanium (SiGe), silicon carbide (SiC), gallium arsenide (GaAs), gallium nitride (GaN), etc. Alternatively, in some examples, the substrate may be an silicon-on-insulator (SOI) substrate, such as silicon-on-glass (SOG) or silicon-on-sapphire (SOP).

The substrate 10 includes a memory region A1 and a logic region A2. Both the memory region A1 and the logic region A2 are formed with a first conductive structure 20. The first conductive structure 20 is formed on the substrate 10, and may be a conductive line or wiring structure embedded in a first dielectric layer 51. The first conductive structure 20 can be manufactured by depositing a layer of the first dielectric layer 51 on the substrate 10. A material of the first dielectric layer 51 may include at least one of silicon oxide, silicon carbide, silicon oxynitride, or silicon nitride. For example, the first dielectric layer 51 can be deposited by chemical vapor deposition (CVD), plasma-enhanced chemical vapor deposition (PECVD), or atomic layer deposition (ALD).

Then, a photoresist layer is formed on the first dielectric layer 51, and the photoresist layer is subjected to exposure-development treatment to define a pattern for the first conductive structure 20 on the photoresist layer. The first dielectric layer 51 is etched according to a patterned photoresist layer to form via holes exposing portions of a top surface of the substrate 10. Next, a conductive material can be deposited by physical vapor deposition (PVD) or CVD to fill the via holes, and the conductive material on a top surface of the first dielectric layer 51 is removed by etching, to form the first conductive structure 20 electrically connected to the substrate 10 in the via holes.

For example, a material of the first conductive structure 20 includes metals (such as copper, aluminum, etc.) or metal alloys.

For example, before forming the first conductive structure 20, a diffusion barrier layer can be deposited first to cover the walls of the via holes. The diffusion barrier layer is disposed between the metal material (such as copper, aluminum) and the first dielectric layer 51, and is configured to support the first conductive structure 20 and isolate the first conductive structure 20 from other film layers, preventing the diffusion of the conductive material. The material of the diffusion barrier layer may include titanium, tantalum, etc.

In this embodiment, the first conductive structure 20 includes a first conductive layer 21, a second conductive layer 22, and a third conductive layer 23 sequentially connected in a direction perpendicular to the substrate 10. The first conductive layer 21, the second conductive layer 22, and the third conductive layer 23 may be conductive lines or pads arranged in a direction extending from the substrate 10.

In the step S102, as shown in FIG. 6, the isolation layer 60 can be formed by deposition using CVD, PECVD, or ALD, and the isolation layer 60 covers a top surface of the first conductive layer. A material of the isolation layer 60 may include at least one of silicon oxide, silicon nitride, or nitrogen-doped silicon oxide.

Then, as shown in FIG. 7, a photoresist layer is formed on the isolation layer 60, and patterned via exposure-development to define a pattern for the first hole 101. The isolation layer 60 is etched according to the patterned photoresist layer until the top surface of the first conductive structure 20 is exposed, and the first hole 101 is formed in the memory region A1.

For example, the isolation layer 60 can be etched by dry etching, wet etching, or a combination thereof to form the first hole 101.

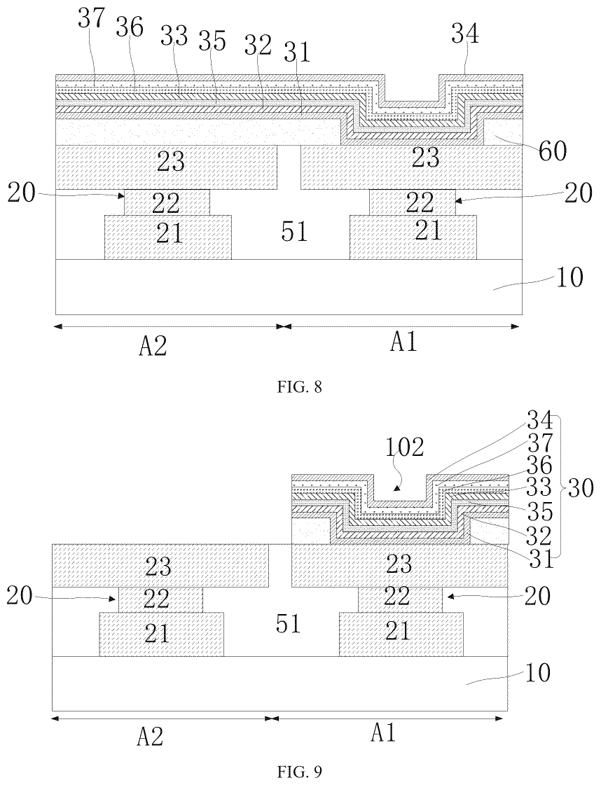

In the step S103, as shown in FIG. 8, a stack including the first electrode layer 31, the first functional layer 32, the second functional layer 33, and the second electrode layer 34 can be sequentially deposited by using PVD or CVD. The first electrode layer 31, the first functional layer 32, the second functional layer 33, and the second electrode layer 34 sequentially cover the walls of the first hole 101 and a top surface of the isolation layer 60. A total thickness of the stack is less than a depth of the first hole 101, and the stack forms a second hole 102 in the upper portion of each first hole 101, with the size of the second hole 102 being smaller than that of the first hole 101.

Then, a photoresist layer is formed on a top surface of the stack, and patterned to define a pattern for the memory cell 30. As shown in FIG. 9, the stack is etched according to the patterned photoresist layer until the top surface of the isolation layer 60 is reached, and the remaining portion of the stack after etching forms the memory cell 30. The memory cell 30 includes the first electrode layer 31, the first functional layer 32, the second functional layer 33, and the second electrode layer 34 sequentially stacked within the first hole 101.

For example, the stack of the first electrode layer 31, the first functional layer 32, the second functional layer 33, and the second electrode layer 34 can be etched by using dry etching to form the memory cell 30.

In some embodiments, as shown in FIG. 9, after forming the memory cell 30, using the top surface of the first dielectric layer 51 as an etching end point, the isolation layer 60 is further etched according to the patterned photoresist layer to ensure complete isolation between adjacent memory cells 30, avoiding residual conductive film layers between adjacent memory cells 30, and reducing risks of leakage current, short-circuits, and crosstalk between adjacent memory cells 30.

For example, the isolation layer 60 can be etched by using wet etching.

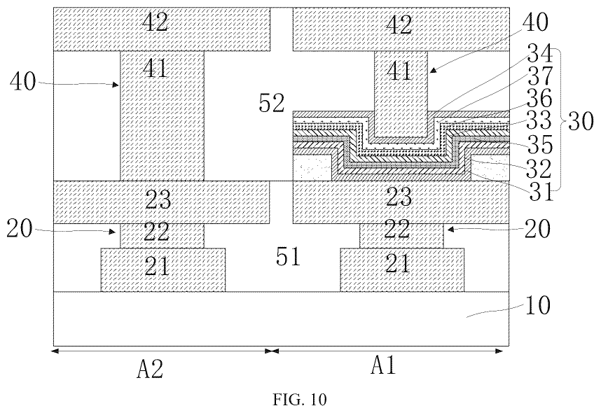

In the step S104, as shown in FIG. 10, a second dielectric layer 52 can be deposited by using ALD, CVD, or PECVD, and the second dielectric layer 52 covers the second electrode layer 34 of the memory cell 30 and the top surface of the first dielectric layer 51 between adjacent memory cells 30. A material of the second dielectric layer 52 may include at least one of silicon oxide, silicon carbide, silicon oxynitride, or silicon nitride.

In this embodiment, by etching away the isolation layer 60 between adjacent memory cells 30, a filling depth between adjacent memory cells 30 is increased, which is beneficial to optimizing the filling quality of the second dielectric layer 52, avoids the formation of voids at the corners of the memory cells 30, ensures good electrical insulation by the second dielectric layer 52, and prevents leakage current in the memory cells 30.

Then, a photoresist layer is formed on a top surface of the second dielectric layer 52, and patterned to define a pattern for the second conductive structure 40. The second dielectric layer 52 is etched according to the patterned photoresist layer to remove the second dielectric layer 52 within the second hole 102, forming a trench penetrating the second dielectric layer 52.

A conductive material is deposited by using PVD or CVD to fill the trench in the second dielectric layer 52 and the second hole 102, and then the conductive material on the top surface of the second dielectric layer 52 is removed by using chemical mechanical polishing (CMP) to form the second conductive structure 40 connected to the memory cell 30 in the trench.

For example, as shown in FIG. 10, the material of the second conductive structure 40 includes metals (such as copper, aluminum, etc.) or metal alloys.

For example, before forming the second conductive structure 40, a diffusion barrier layer can be deposited first to cover the wall of the trench to isolate the second conductive structure 40 from other film layers and prevent the diffusion of the conductive material.

In the embodiment, as shown in FIG. 10, the second conductive structure 40 includes a fourth conductive layer 41 and a fifth conductive layer 42 sequentially connected in a direction perpendicular to the substrate 10. The fourth conductive layer 41 and the fifth conductive layer 42 may be conductive lines or pads arranged in a direction extending from the substrate 10. Both the memory region A1 and the logic region A2 are formed with the second conductive structure 40, and the second conductive structure 40 in the logic region A2 is connected to the first conductive structure 20.

In some embodiments, the material of the selector layer includes at least one of niobium oxide, vanadium oxide, iron oxide, neodymium nickel oxide, samarium nickel oxide, lanthanum cobalt oxide, gadolinium cobalt oxide, germanium telluride, aluminum telluride, boron telluride, germanium selenide, germanium sulfide, or antimony telluride.

The selector layer may be a single-layer structure or a multi-layer structure. For example, the selector layer may include a single niobium oxide layer. Alternatively, the selector layer may include a stacked structure of a niobium oxide layer and an antimony telluride layer.

The material of the resistive switching layer includes at least one of tantalum oxide, titanium oxide, hafnium oxide, zirconium oxide, silicon oxide, magnesium oxide, aluminum nitride, germanium antimony telluride, scandium antimony telluride, indium silver antimony telluride, germanium antimonide, germanium telluride, antimony telluride, copper sulfide, germanium sulfide, germanium selenide, zinc sulfide, aluminum borate, strontium titanate, zirconium titanate, barium titanate, hafnium zirconium oxide, or hafnium aluminum oxide.

The resistive switching layer may be a single-layer structure or a multi-layer structure. For example, the resistive switching layer may include a single tantalum oxide layer. Alternatively, the resistive switching layer may include a stacked structure of a tantalum oxide layer and a titanium oxide layer.

After forming the first functional layer 32 and the second functional layer 33, an annealing treatment is performed on the first functional layer 32 and the second functional layer 33 together.

In the fabrication process for the memory with the 1S1R architecture, after forming the selector layer and the resistive switching layer, separate annealing steps are typically required for each. For the selector layer, the annealing treatment can improve its switching characteristics, such as reducing the switching voltage and improving the switching speed. For the resistive switching layer, the annealing treatment can adjust its resistive switching characteristics, such as changing the resistive switching threshold and improving the resistive switching stability and endurance.

In this embodiment, by reasonably designing the materials for the selector layer and the resistive switching layer of the memory cell 30, the first functional layer 32 and the second functional layer 33 of the memory cell 30 can be annealed in the same step, saving one annealing process, thereby simplifying the production process, improving the production efficiency, and reducing the cost.

In some embodiments, the material of the first electrode layer 31 may include at least one of vanadium, niobium, ruthenium, tungsten, tantalum, tantalum nitride, titanium, titanium nitride, titanium tungsten, aluminum, titanium aluminum tungsten, yttrium, yttrium oxide, indium tin oxide, aluminum titanium nitride, aluminum nitride, aluminum titanium nitride, hafnium, iridium, manganese, zinc, platinum, palladium, or copper. The first electrode layer 31 may be a single-layer structure or a multi-layer structure.

The material selection range of the second electrode layer 34 is the same as that of the first electrode layer 31, and will not be repeated here.

In some embodiments, as shown in FIG. 8 and FIG. 9, forming the memory cell 30 further includes: forming an intermediate layer 35 between the first functional layer 32 and the second functional layer 33.

After forming the first functional layer 32 and before forming the second functional layer 33, the intermediate layer 35 can be deposited on a side of the first functional layer 32 away from the substrate 10 using a CVD or ALD process. The intermediate layer 35 is configured to prevent the performance degradation of the memory cell 30 caused by the mutual diffusion of materials between the first electrode layer 31 and the first functional layer 32, thereby improving the reliability and performance stability of the memory cell 30.

In some embodiments, a thermal conductivity of the intermediate layer 35 is less than that of the resistive switching layer. For example, the thermal conductivity of the selector layer is 0.3 W/m·K to 1.5 W/m·K. A thermal conductivity of the resistive switching layer is 2.2 W/m·K to 5 W/m·K. The thermal conductivity of the intermediate layer 35 is 0.2 W/m·K to 2 W/m·K. In this way, the intermediate layer 35 prevents the transfer of heat from the selector layer to the resistive switching layer, which can shorten the time required for the selector layer to reach its turn-on temperature and reduce a turn-on voltage (Vth) of the memory cell 30. Meanwhile, the intermediate layer 35 can improve the thermal stability of the selector layer, delay the temperature decrease of the selector layer, and reduce a write voltage and read voltage of the memory cell 30.

In an example, the thermal conductivity of the selector layer is 0.3 W/m·K, the thermal conductivity of the resistive switching layer is 2.2 W/m·K, and the thermal conductivity of the intermediate layer 35 is 0.2 W/m·K. In another example, the thermal conductivity of the selector layer is 1.5 W/m·K, the thermal conductivity of the resistive switching layer is 5 W/m·K, and the thermal conductivity of the intermediate layer 35 is 2 W/m·K. In another example, the thermal conductivity of the selector layer is 1 W/m·K, the thermal conductivity of the resistive switching layer is 4 W/m·K, and the thermal conductivity of the intermediate layer 35 is 3 W/m·K.

Further, the electrical conductivity of the intermediate layer 35 ranges from 10⁻⁷ S/m to 10⁻² S/m. For example, 10⁻⁷ S/m, 10⁻⁶ S/m, 10⁻⁵ S/m, 10⁻⁴ S/m, 10⁻³ S/m, or 10⁻² S/m. In this way, the intermediate layer 35 has good conductivity and certain thermal insulation properties, so that when the intermediate layer 35 is disposed between the selector layer and the resistive switching layer, it does not affect the conduction between the selector layer and the resistive switching layer, and can also reduce a turn-on voltage of the memory cell 30.

In some embodiments, the material of the intermediate layer 35 includes at least one of amorphous carbon, silicon carbide, tellurium carbide, tellurium carbon sulfide, molybdenum sulfide, tungsten sulfide, molybdenum telluride, indium gallium zinc oxide, indium aluminum zinc oxide, tin-doped indium oxide, manganese telluride, tungsten telluride, or zinc-doped indium oxide.

The intermediate layer 35 may be a single-layer structure or a multi-layer structure. For example, the intermediate layer 35 may include a single amorphous carbon layer. Alternatively, the intermediate layer 35 may include a stacked structure of an amorphous carbon layer and an indium gallium zinc oxide layer.

In some embodiments, as shown in FIG. 8 and FIG. 9, forming the memory cell 30 further includes: forming a barrier layer 36 between the selector layer and the first electrode layer 31, or between the selector layer and the second electrode layer 34. The electron affinity of the barrier layer 36 is less than that of the selector layer. The barrier layer 36 is configured to localize electrons and prevent electron leakage, thereby reducing the leakage current of the memory cell 30.

For example, the material of the barrier layer 36 includes at least one of zinc oxide, nickel oxide, titanium oxide, chromium oxide, molybdenum oxide, tungsten oxide, bismuth oxide, antimony oxide, barium titanate, indium oxide, vanadium oxide, strontium titanate, aluminum titanate, manganese oxide, or gallium nitride.

In some embodiments, as shown in FIG. 8 and FIG. 9, forming the memory cell 30 further includes: forming a buffer layer 37 between the selector layer and the barrier layer 36. The electron affinity of the buffer layer 37 is between the electron affinity of the selector layer and the electron affinity of the barrier layer 36.

For example, the material of the buffer layer 37 includes at least one of titanium oxide, nickel oxide, zinc oxide, chromium oxide, molybdenum oxide, tungsten oxide, bismuth oxide, antimony oxide, indium oxide, vanadium oxide, niobium oxide, manganese oxide, neodymium oxide, strontium oxide, germanium oxide, lanthanum oxide, hafnium oxide, gallium oxide, aluminum oxide, zirconium oxide, silicon oxide, ytterbium oxide, or magnesium oxide.

The buffer layer 37 is configured to buffer a difference in electron affinity between the selector layer and the barrier layer 36, avoiding performance fluctuations in the memory cell 30 caused by an excessively large difference in electron affinity between the selector layer and the barrier layer 36. Meanwhile, when the memory cell 30 is turned on, and the selector layer transitions from the high-resistance state to the low-resistance state, the voltage drop across the barrier layer 36 increases. By disposing the buffer layer 37 between the selector layer and the barrier layer 36 in the present disclosure, the buffer layer 37 can reduce the voltage drop across the barrier layer 36, preventing the barrier layer 36 from being broken down by high voltage drop, further reducing the leakage risk of the memory cell 30, improving the performance stability and reliability of the memory cell 30, and facilitating optimizing the performance of the device and extending its service life.

An example where the first functional layer 32 is the selector layer and the second functional layer 33 is the resistive switching layer is taken for description. A difference between a work function of the first electrode layer 31 and the electron affinity of the selector layer is greater than 2 eV. A difference between a work function of the second electrode layer 34 and the electron affinity of the barrier layer 36 is greater than 2 eV.

The electron affinity of the selector layer is 2 eV to 4.5 eV. The electron affinity of the barrier layer 36 is 1 eV to 2 eV. The electron affinity of the buffer layer 37 is 1 eV to 4.5 eV.

In this way, a surface of one side of the selector layer is in contact with the first electrode layer 31, thus forming a barrier at the interface between the selector layer and the first electrode layer 31. A barrier is formed at the interface between a surface of one side of the barrier layer 36 away from the buffer layer 37 and the second electrode layer 34. In this way, electrons can be localized at the barrier interface between the selector layer and the first electrode layer 31, and at the barrier interface between the barrier layer 36 and the second electrode layer 34, preventing electron leakage, and thereby reducing the leakage current of the memory cell 30.

In some embodiments, the intermediate layer 35 is formed between the first functional layer 32 and the second functional layer 33 of the memory cell 30, and the buffer layer 37 and the barrier layer 36 are sequentially formed between the selector layer and its adjacent electrode layer.

According to the semiconductor structure and the fabrication method thereof in the present disclosure, by configuring the memory cell 30 to form the second hole 102 facing away from the substrate 10, the contact area between the second conductive structure 40 and the second electrode layer 34 is increased. Consequently, the drive current, read/write capability, and gating capability of the memory cell 30 are significantly improved, which can improve the integration density of the memory cell 30 with the 1S1R architecture, offering broad application prospects in the field of high-performance memories, especially in scenarios requiring high density, low power consumption, and fast read/write capabilities, and meeting the demands of continuous advancement in memory technology and growing needs.

The technical features in the above-mentioned embodiments can be arbitrarily combined. To make the description concise, all possible combinations of the technical features in the above-mentioned embodiments are not described. However, as long as there is no contradiction between the combinations of these technical features, they should be considered to be within the scope of protection of the description.

The above-mentioned embodiments only describe several implementations of the present disclosure, and their descriptions are specific and detailed, but should not be understood as a limitation on the protection scope of the patent disclosure. It should be noted that for those of ordinary skill in the art, without departing from the concept of the present disclosure, various variations and improvements can also be made, which all fall within the protection scope of the present disclosure. Therefore, the protection scope of the present disclosure should be subject to the appended claims.

What is claimed is:

1. A semiconductor structure, comprising:
a substrate;
a first conductive structure disposed on the substrate;
a memory cell disposed on a side of the first conductive structure away from the substrate, the memory cell comprising a first electrode layer, a first functional layer, a second functional layer, and a second electrode layer sequentially stacked in a direction away from the substrate, the memory cell forming a second hole above the first conductive structure, an opening direction of the second hole facing away from the substrate, and one of the first functional layer and the second functional layer being a selector layer, and the other being a resistive switching layer; and
a second conductive structure disposed on a side of the memory cell away from the substrate, the second conductive structure being in contact with the second electrode layer on a sidewall and a bottom wall of the second hole.

2. The semiconductor structure according to claim 1, further comprising:
an isolation layer disposed on a side of the first conductive structure away from the substrate, the isolation layer being penetrated by a first hole;
wherein the memory cell is disposed corresponding to the first hole and forms the second hole above the first hole, the first electrode layer covers the first conductive structure on a bottom wall of the first hole, a sidewall of the first hole, and a portion of a top surface of the isolation layer peripheral to the first hole, and the first functional layer, the second functional layer, and the second electrode layer sequentially cover the first electrode layer.

3. The semiconductor structure according to claim 1, wherein the memory cell further comprises an intermediate layer disposed between the first functional layer and the second functional layer; and
a material of the intermediate layer comprises at least one of amorphous carbon, silicon carbide, tellurium carbide, tellurium carbon sulfide, molybdenum sulfide, tungsten sulfide, molybdenum telluride, indium gallium zinc oxide, indium aluminum zinc oxide, tin-doped indium oxide, manganese telluride, tungsten telluride, or zinc-doped indium oxide.

4. The semiconductor structure according to claim 1, wherein a material of the selector layer comprises at least one of niobium oxide, vanadium oxide, iron oxide, neodymium nickel oxide, samarium nickel oxide, lanthanum cobalt oxide, gadolinium cobalt oxide, germanium telluride, aluminum telluride, boron telluride, germanium selenide, germanium sulfide, or antimony telluride; and
a material of the resistive switching layer comprises at least one of tantalum oxide, titanium oxide, hafnium oxide, zirconium oxide, silicon oxide, magnesium oxide, aluminum nitride, germanium antimony telluride, scandium antimony telluride, indium silver antimony telluride, germanium antimonide, germanium telluride, antimony telluride, copper sulfide, germanium sulfide, germanium selenide, zinc sulfide, aluminum borate, strontium titanate, zirconium titanate, barium titanate, hafnium zirconium oxide, or hafnium aluminum oxide.

5. The semiconductor structure according to claim 4, wherein the memory cell further comprises a barrier layer disposed between the selector layer and the first electrode layer, or between the selector layer and the second electrode layer;
an electron affinity of the barrier layer is less than an electron affinity of the selector layer; and
a material of the barrier layer comprises at least one of zinc oxide, nickel oxide, titanium oxide, chromium oxide, molybdenum oxide, tungsten oxide, bismuth oxide, antimony oxide, barium titanate, indium oxide, vanadium oxide, strontium titanate, aluminum titanate, manganese oxide, or gallium nitride.

6. The semiconductor structure according to claim 5, wherein the memory cell further comprises a buffer layer disposed between the selector layer and the barrier layer;
an electron affinity of the buffer layer is between the electron affinity of the selector layer and the electron affinity of the barrier layer; and
a material of the buffer layer comprises at least one of titanium oxide, nickel oxide, zinc oxide, chromium oxide, molybdenum oxide, tungsten oxide, bismuth oxide, antimony oxide, indium oxide, vanadium oxide, niobium oxide, manganese oxide, neodymium oxide, strontium oxide, germanium oxide, lanthanum oxide, hafnium oxide, gallium oxide, aluminum oxide, zirconium oxide, silicon oxide, ytterbium oxide, or magnesium oxide.

7. The semiconductor structure according to claim 1, wherein the substrate comprises a memory region and a logic region, and both the memory region and the logic region are formed with the first conductive structure.

8. The semiconductor structure according to claim 7, wherein the memory cell is disposed on a side of the first conductive structure in the memory region away from the substrate.

9. The semiconductor structure according to claim 8, wherein the memory cell comprises a plurality of memory cells arranged spaced apart in a direction perpendicular to the substrate, and the plurality of memory cells are connected through the second conductive structure.

10. The semiconductor structure according to claim 1, wherein the first conductive structure comprises a first conductive layer, a second conductive layer, and a third conductive layer sequentially connected in a direction perpendicular to the substrate, and the second conductive structure comprises a fourth conductive layer and a fifth conductive layer sequentially connected in the direction perpendicular to the substrate.

11. The semiconductor structure according to claim 3, wherein a thermal conductivity of the intermediate layer is less than that of the resistive switching layer.

12. A method for fabricating a semiconductor structure, the method comprising:
providing a substrate and forming a first conductive structure on the substrate;
forming an isolation layer on a side of the first conductive structure away from the substrate, and etching the isolation layer to form a first hole, the first hole exposing a portion of a top surface of the first conductive structure;
forming a first electrode layer, a first functional layer, a second functional layer, and a second electrode layer sequentially to form a memory cell, the memory cell forming a second hole above the first conductive structure, an opening direction of the second hole facing away from the substrate, and one of the first functional layer and the second functional layer being a selector layer, and the other being a resistive switching layer; and
forming a second conductive structure on a side of the memory cell away from the substrate, the second conductive structure being in contact with the second electrode layer on a sidewall and a bottom wall of the second hole.

13. The method for fabricating the semiconductor structure according to claim 12, wherein a material of the selector layer comprises at least one of niobium oxide, vanadium oxide, iron oxide, neodymium nickel oxide, samarium nickel oxide, lanthanum cobalt oxide, gadolinium cobalt oxide, germanium telluride, aluminum telluride, boron telluride, germanium selenide, germanium sulfide, or antimony telluride;
a material of the resistive switching layer comprises at least one of tantalum oxide, titanium oxide, hafnium oxide, zirconium oxide, silicon oxide, magnesium oxide, aluminum nitride, germanium antimony telluride, scandium antimony telluride, indium silver antimony telluride, germanium antimonide, germanium telluride, antimony telluride, copper sulfide, germanium sulfide, germanium selenide, zinc sulfide, aluminum borate, strontium titanate, zirconium titanate, barium titanate, hafnium zirconium oxide, or hafnium aluminum oxide; and
after forming the first functional layer and the second functional layer, performing an annealing treatment on both the first functional layer and the second functional layer.

14. The method for fabricating the semiconductor structure according to claim 12, wherein forming the memory cell further comprises: forming an intermediate layer between the first functional layer and the second functional layer.

15. The method for fabricating the semiconductor structure according to claim 12, wherein forming the memory cell further comprises: forming a barrier layer between the selector layer and the first electrode layer, or between the selector layer and the second electrode layer, where an electron affinity of the barrier layer is less than an electron affinity of the selector layer; and
forming the memory cell further comprises: forming a buffer layer between the selector layer and the barrier layer, where an electron affinity of the buffer layer is between the electron affinity of the selector layer and the electron affinity of the barrier layer.

16. The method for fabricating the semiconductor structure according to claim 12, wherein forming the first electrode layer, the first functional layer, the second functional layer, and the second electrode layer sequentially to form the memory cell, comprises:
depositing the first electrode layer, the first functional layer, the second functional layer, and the second electrode layer sequentially to form a stacked structure, where the first electrode layer, the first functional layer, the second functional layer, and the second electrode layer sequentially cover a wall of the first hole and a top surface of the isolation layer; and
etching the stacked structure down to the top surface of the isolation layer to form the memory cell.

17. The method for fabricating the semiconductor structure according to claim 16, wherein a total thickness of the stacked structure is less than a depth of the first hole.

18. The method for fabricating the semiconductor structure according to claim 16, wherein the stacked structure forms the second hole in the upper portion of the first hole, with a size of the second hole being smaller than that of the first hole.

19. The method for fabricating the semiconductor structure according to claim 12, wherein forming the memory cell comprises:
forming a plurality of memory cells spaced apart in a direction perpendicular to the substrate, the plurality of memory cells being connected through the second conductive structure.

20. The method for fabricating the semiconductor structure according to claim 12, wherein a thermal conductivity of the intermediate layer is less than that of the resistive switching layer.
